(19) United States
(12) Patent Application Publication
(10) Pub. No.: US 2008/0193802 A1
(43) Pub. Date: Aug. 14, 2008

(54) Protein-coupled bioelectric solar cell

(75) Inventors: Corey James Centen, Ottawa (CA); Edward Thomas Chouchani, Ottawa (CA)

Correspondence Address: Corey J Centen, 24 Herridge St., Ottawa, K1S 0G7, omitted

(73) Assignee: Mobilab Technologies inc.

(21) Appl. No.: 11/500,686

(22) Filed: Aug. 9, 2006

(51) Int. Cl. H01L 31/04; H01M 8/02

(52) U.S. Cl. 429/12; 136/252

(57) ABSTRACT

A Protein-Coupled Bioelectric Solar Cell having multiple compartments separated by active protein layers in which these layers contain either Bacteriorhodopsin or Cytochrome proteins. The biochemical reactions of these layers are coupled to transform solar energy into electricity. The Bacteriorhodopsin provides the solar energy conversion while the Cytochrome is sandwiched between microporous electrodes and provides the electromotive force. The device compartmentalization and the microporous electrodes facilitate the production of a cyclical proton flow and its subsequent conversion into an electron flow by the proteins. This device enables high efficiency solar energy conversion in a lightweight, easily manufactured, modular device. This design enables the proteins to be encapsulated in biocompatible polymer gels that prolong their lifecycle while retaining their biological function. Through the use of separate layers for each type of protein, sensitive proteins can be protected and efficiency can be improved by encapsulating each protein in its ideal conditions.

### CROSS-REFERENCE TO RELATED APPLICATIONS

Not Applicable

### FEDERALLY SPONSORED RESEARCH

Not Applicable

### SEQUENCE LISTING OR PROGRAM

Not Applicable

### BACKGROUND OF THE INVENTION

1. Field of Invention

This invention relates to power sources, specifically to methods of generating power using biological materials.

2. Prior Art

Previously, biological solar cells have succumbed to high levels of instability due to degradation of the organic materials. Low power outputs and low efficiency have plagued these devices: delicate biological materials often lose functionality under extended solar radiation and outside of their natural environment. It has been a significant challenge to extract useable electricity from many organic and biological materials.

One of the earliest technologies to use organic molecules for power generation is the dye-sensitized solar cell. These cells use organic dyes to capture incoming light energy converting it into useable electricity (Coronado et al., Hybrid molecular materials for optoelectronic devices, 2005, 3593-3597, J. Mater. Chem., vol. 15). These cells are extremely promising due to their low manufacturing costs and relatively simple design. Unfortunately, the energy conversion efficiency of these cells has yet to exceed 10% and the materials begin to degrade after a limited amount of use.

In more recent developments, biological materials, such as proteins, have been used to generate electricity. In one incarnation, researchers at the Massachusettes Institute of Technology (MIT) have created solid state solar cells using peptide stabilization of the photosystem I complex found in plants (Kiley et al., Self-Assembling Peptide Detergents Stabilize Isolated Photosystem I on a Dry Surface for an Extended Time, PLoS Biology, 2005, 1180-1186, vol. 3, no. 7). Photosystem I is a trimeric complex forming a large disc. The protein complex is an integral part of the photosynthetic reaction centre and is responsible for capturing incident light and helping convert it into useful energy for the plant. Although encouraging, solar cells using the photosystem I complex suffer from a number of potential problems. The long term stability of the active components in such a ‘photosynthetic cell’ does not rival current solar technologies. In addition, Photosystem I is a complex protein group with a relatively low stability once isolated from its native environment. Currently, the maximum efficiency obtainable with such cells is low and the relatively large size of the protein complex limits the number of molecules that can be positioned on a planar surface of predetermined dimensions.

Another biological complex currently under investigation is the highly stable protein Bacteriorhodopsin. In comparison to photosystem I and most other biological materials, it is easily isolated and stabilized and it maintains its activity under a variety of stresses. A significant amount of research has been dedicated to the stabilization of this protein in polymer films on solid substrates. These efforts have shown that when immobilized and oriented, Bacteriorhodopsin is able to generate a photocurrent and can remain fully active over many years. However, the photocurrent generated by these Bacteriorhodopsin films is transient and extremely small (Koyama et al., Molecular Organization of Bacteriorhodopsin Films in Optoelectronic Devices, Advanced Materials, 1995, 590-594, vol. 7, no. 6).

Cytochrome c Oxidase and Cytochrome c are two other proteins that have garnered significant attention in the field of bioenergetics. Under normal conditions, Cytochrome c Oxidase is the protein that accepts free electrons in the reduction of oxygen to water. However, Wikstrom et al. first demonstrated that, under favourable conditions, the protein could drive a reverse reaction and become an electron donor (Wikström et al., Energy-dependent reversal of the cytochrome oxidase reaction, Biochemistry, 1981, 4051-4054, vol. 78, no. 7).

Ho, Montemagno et al. have developed a membrane material incorporating both the proteins Bacteriorhodopsin and Cytochrome c Oxidase (Ho et al., Fabrication of biomolecule-copolymer hybrid nanovesicles as energy conversion systems, Nanotechnology, 2005, 3120-3132, vol. 16) (US Pat. App. No. 2004/0049230, ‘Biomimetic Membranes’, Montemagno, Schmidt, Tozzi, Pub. Date: Mar. 11, 2004). This membrane is similar to the proteins' natural lipid environments and allows the proteins to work together in one material. This research is a step forward in the development of a new type of biomaterial that can be applied to solar energy conversion. However, the material proposed by these researchers still faces serious challenges regarding its integration into an efficient power-producing module. First, the material proposed by Ho, Montemagno et al. requires integration of both proteins into the same layer. This limits the amount of active Bacteriorhodopsin-covered surface that can be exposed to sunlight. In addition, the material must be extremely thin limiting its robustness. The material also faces limitations when orienting the two proteins. For proper operation of the material, each protein must be independently oriented in one specific direction. However, both proteins are placed in the same planar layer preventing efficient orientation of both proteins using electrophoretic deposition or any other means of orientation.

Another major disadvantage of the invention of patent application US2004/0049230 is that only one layer is used to support both proteins. Cytochrome c Oxidase is well known to be far less stable than the protein Bacteriorhodopsin. In any external environmental conditions, including light exposure, this protein may degrade rapidly. If Cytochrome c Oxidase and Bacteriorhodopsin are to work in tandem in one layer, it would be very difficult, if not impossible, to design a device in which the Cytochrome proteins are not exposed to the damaging effects of light absorption. Furthermore, the invention of Montemagno does not make use of the protein Cytochrome c and only uses the protein Cytochrome c Oxidase. It has been established that the omission of this protein from the electron pathway limits the ability of Cytochrome c Oxidase to act as an efficient electron donor to an electrode. Patent Application US2004/0049230 refers to a ‘Biomimetic Membrane’ material but fails to fully explain how such a membrane would be integrated into any type of commercial power producing device.

3. Advantages

Accordingly one or more embodiments of the present invention may have one or more of the following advantages:
a. to provide a new solar-based power source using biological materials
b. to provide a new solar-based power source that is inexpensive to manufacture
c. to provide a new solar-based power source in which the active biological material is composed of proteins immobilized and highly stabilized
d. to provide a compartmentalized solar-based power source that couples Bacteriorhodopsin and the Cytochrome protein reactions effectively and efficiently
e. to provide a compartmentalized solar-based power source that efficiently orients Bacteriorhodopsin and the Cytochrome proteins separately and therefore, more efficiently
f. to provide a compartmentalized solar-based power source in which the proteins are in separate layers so as to increase orientation of the proteins thereby increasing efficiency
g. to provide a compartmentalized solar-based power source in which the proteins are in separate layers so as to increase the amount of photoactive material exposed to sunlight thereby increasing efficiency
h. to provide a solar-based power source that may be constructed in the solid state, absent of aqueous media
i. to provide a solar-based biological power source in which biological materials not tailored for sun exposure are protected from all incoming light
j. to provide a solar-based biological power source in which only the light sensitive and optically stable protein(s) is/are exposed to light while all other biological material is protected from all environmental conditions, including light
k. to provide a biological solar-based power source that may utilize the Cytochrome c protein to complete an electron pathway from Cytochrome c Oxidase to an electrode
l. to provide a new solar-based power source that may be partially transparent and aesthetically superior to conventional solar technologies

Further advantages are to provide a new solar-based power source that is thin, lightweight and easily tailored to a number of applications with nanoscale limitations on size. Such a device can be altered for use in integrated circuits, optoelectronics and fibre optics. Still further advantages will become apparent from a consideration of the ensuing description and drawings.

### SUMMARY

In accordance with the present invention the Protein-Coupled Bioelectric Solar Cell comprises a compartmentalized system in which isolated layers containing either the protein Bacteriorhodopsin or the proteins Cytochrome c Oxidase and Cytochrome c work in tandem to convert solar radiation into useable electrical power.

### DRAWINGS—FIGURES

FIG. 1 is a backbone ribbon schematic of the protein Bacteriorhodopsin as it exists in its native membrane where it pumps protons from its cytosolic to extracellular regions.

FIG. 2 is a structural representation of Cytochrome c Oxidase in membrane interacting with Cytochrome c.

FIG. 3 is a UV visual absorption spectrum of purified purple membrane fragments containing the protein Bacteriorhodopsin.

FIG. 4 is the forward catalytic reaction carried out by Cytochrome c Oxidase in reducing oxygen to water.

FIG. 5 is the reverse half-reaction carried out by Cytochrome c Oxidase when subjected to a potential energy gradient.

FIG. 6 is a detailed schematic view of a microporous gold electrode.

FIG. 7 is an electron micrograph of the surface of a microporous gold electrode.

FIG. 8 is the organic tethering of Cytochrome c to a microporous gold electrode.

FIG. 9 is the natural association of Cytochrome c Oxidase with Cytochrome c organically tethered to a microporous gold electrode.

FIG. 10 is the organic linking of Cytochrome c and Cytochrome c Oxidase proteins using glutaric dialdehyde.

FIG. 11 is a schematic of the mould in which the solar cell is formed.

FIG. 12 is an overview of the gelation reaction of the proton conducting material, in this case a sol-gel material (ORMOSIL) using oxysilane precursors.

FIG. 13 is a schematic of the mould containing the first layer of sol-gel (ORMOSIL) with one set of embedded electrodes.

FIG. 14 includes all components of FIG. 13 as well as an added spacer.

FIG. 15 includes all components of FIG. 14 as well as the two layers of oppositely oriented purple membrane.

FIG. 16 is an overview of the application of an electric field to a layer of purple membrane for the purpose of protein orientation.

FIG. 17 includes all components of FIG. 15 as well as the top layer of ORMOSIL and the second set of electrodes.

FIG. 18 is a figure showing purple membrane fragments entrapped, oriented and immobilized in ORMOSIL.

FIG. 19 is a side-view schematic of the entire power unit.

FIG. 20 includes all components of FIG. 17 as well as the protective cover unit.

FIG. 21 is a side-view schematic of the entire power unit undergoing solar to electric energy conversion.

FIG. 22 is an isolated view of the Cytochrome c/Cytochrome c Oxidase complex reaction induced by a proton gradient.

FIG. 23 is the modular unit consisting of two microporous electrodes and the Cytochrome c/Cytochrome c Oxidase monolayer.

FIG. 24 is a two-celled device in which the modular unit of FIG. 23 separates two compartments of differing acidities.

FIG. 25 represents a possible parallel configuration of the protein layers of the present invention.

FIG. 26 is a schematic showing the use of a conductive graphite doped sol-gel material to increase the electrical connection between the Cytochrome c Oxidase protein and the electrode.

FIG. 27 is a schematic showing an electrode configuration in which the Cytochrome c Oxidase is tethered to the counter electrode.

### DRAWINGS—REFERENCE NUMERALS

| | | |
|---|---|---|
| 28 Bacteriorhodopsin | 30 solar illumination | 32 proton |
| | | translocation |
| 34 Cytochrome c | 36 Cytochrome c | 38 electron flow |
| | Oxidase | path |
| 40 oxygen | 42 electron transfer | 44 pore |
| | cascade | |
| 46 cysteine-102 | 48 maleimide layer | 50 bare electrode |
| residue | | |
| 52 glutaric | 54 Cytochrome c | 56 Cytochrome |
| dialdehyde | Oxidase cross-linkage | c/Cytochrome c |
| | | Oxidase cross- |
| | | linkage |
| 58 first modified | 60 | 62 3-aminopropyl- |
| active electrode | phenyltrimethoxysilane | trimethoxysilane |
| 64 2-(3,4- | 66 hydrochloric acid | 68 long chain |
| epoxycyclohexyl)- | | mixture of |
| ethyltrimethoxysilane | | precursor |
| | | monomers |
| 70 first set of | 72 bottom ORMOSIL | 74 first counter |
| grooves | layer | electrode |
| 76 second set of | 78 spacer | 80 first purple |
| grooves | | membrane layer |
| 82 second purple | 84 second ORMOSIL | 86 second active |
| membrane layer | layer | modified |
| | | electrode |
| 88 second counter | 90 protective cover | 92 transparent |
| electrode | unit | panels |
| 94 first compartment | 96 second compartment | 98 third |
| | | compartment |
| 100 fourth | 102 heme group of | 104 Cytochrome c |
| compartment | cytochrome c | Oxidase proton |
| | | channel |
| 106 free electrons | 108 accepting | 110 heme a3 group |
| | electrons | |
| 112 Cu_{B} group | 114 electron transfer | 116 heme a group |
| | to cytochrome c | |
| 118 Cu_{A} group | 120 cyclic electron | 122 circuit |
| | flow | |
| 124 Cytochrome | 126 series connection | 128 external load |
| complex | | |
| 130 Fuel Cell Comp. A | 132 Fuel Cell Comp. B | 134 Parallel |
| | | Bacteriorhodopsin |
| | | Layer |
| 136 Parallel | 138 Conducting | 140 Cytochrome c |
| Cytochrome Layer | Material | Oxidase Tether |

### DETAILED DESCRIPTION

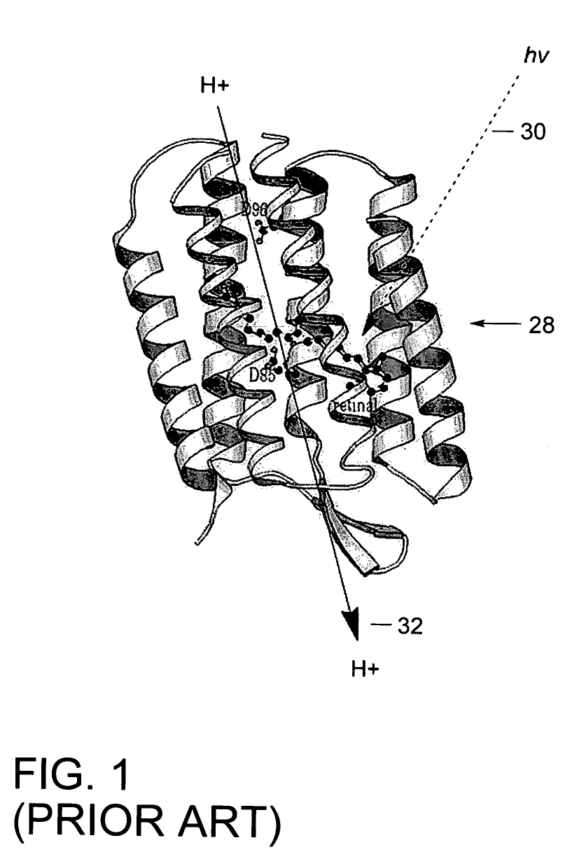

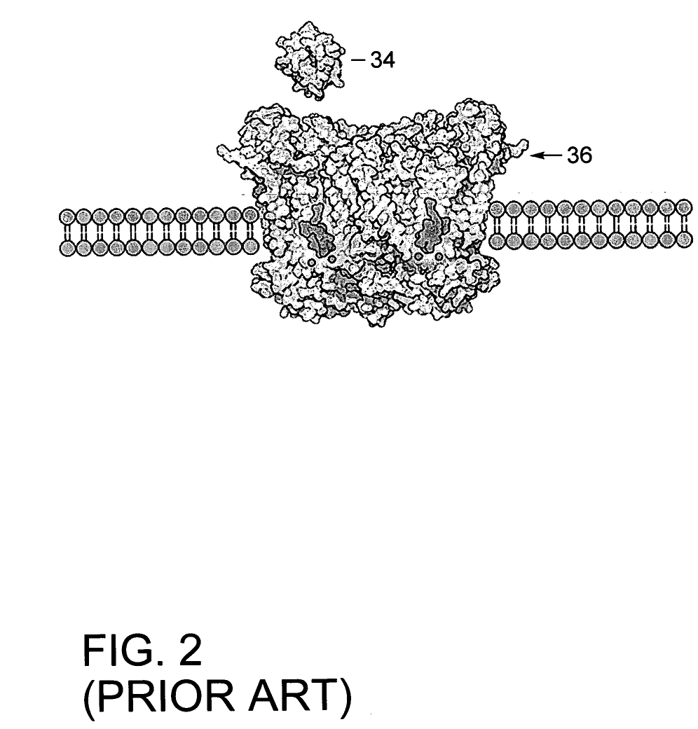

To understand the mechanism that drives the protein-coupled bioelectric solar cell of the present invention, it is best to first become familiar with its fundamental components: the proteins Bacteriorhodopsin shown in FIG. 1, Cytochrome c, and Cytochrome c Oxidase shown in FIG. 2.

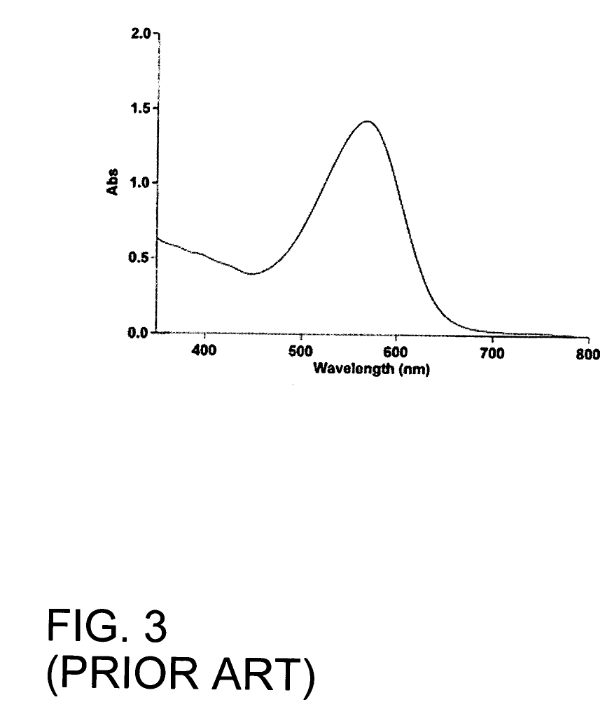

Bacteriorhodopsin 28 (26 kD) is a well characterized, highly stable protein isolated from the cell membrane of Halobacterium Salinarium (formerly Halobacterium Halobium). Upon solar illumination 30, the protein generates a proton gradient across the cell membrane. This proton gradient is used to drive the production of energy for the cell in the form of adenosine triphosphate (ATP) using the protein ATP synthase. The proton transport mechanism of Bacteriorhodopsin is facilitated by absorption of light in the 500-650 nm wavelength region shown in FIG. 3. Upon absorption of such light, the protein undergoes a number of conformational changes resulting in proton translocation 32. The time required for one complete cycle of the proton translocating mechanism is less than three milliseconds (L. Zhang et al., High-Performance Photovoltaic Behaviour of Oriented Purple Membrane Polymer Composite Films, Biophysical Journal, 2003, 2502-2507, vol. 84).

Bacteriorhodopsin exists in highly concentrated clusters termed purple membrane. Within these clusters the concentration of Bacteriorhodopsin is roughly 75%, this is equivalent to approximately 10 lipid molecules per protein. These protein clusters, embedded in their native lipid matrix can be isolated very effectively through lysis of the bacterial cells followed by differential centrifugation to remove all other cellular debris. The result is highly pure and highly stable purple membrane fragments. In this embodiment of the invention, a modified version of the procedure of Oesterhelt and Stoeckenius was used to isolate the fragments (D. Oesterhelt et al., Isolation of the Cell Membrane of Halobacterium Halobium and Its Fractionation into Red and Purple Membrane, Methods of Enzymology, Biomembranes, 1974, 667-678, vol. 31).

Cytochrome c 34 (12.588 kDa) is a common electron transport protein found loosely associated with the inner membrane of the mitochondrion. It plays an essential role in cellular respiration. The protein is not anchored to any cell membrane but rather acts as a mediator between the other respiratory proteins Cytochrome bcl and Cytochrome c Oxidase 36. The electrons transported by Cytochrome c are initially obtained from the breakdown of sugar in the cell. The resulting electrons are eventually used to drive the reduction of oxygen to water—a very complex biological process in which Cytochrome c Oxidase is intimately involved.

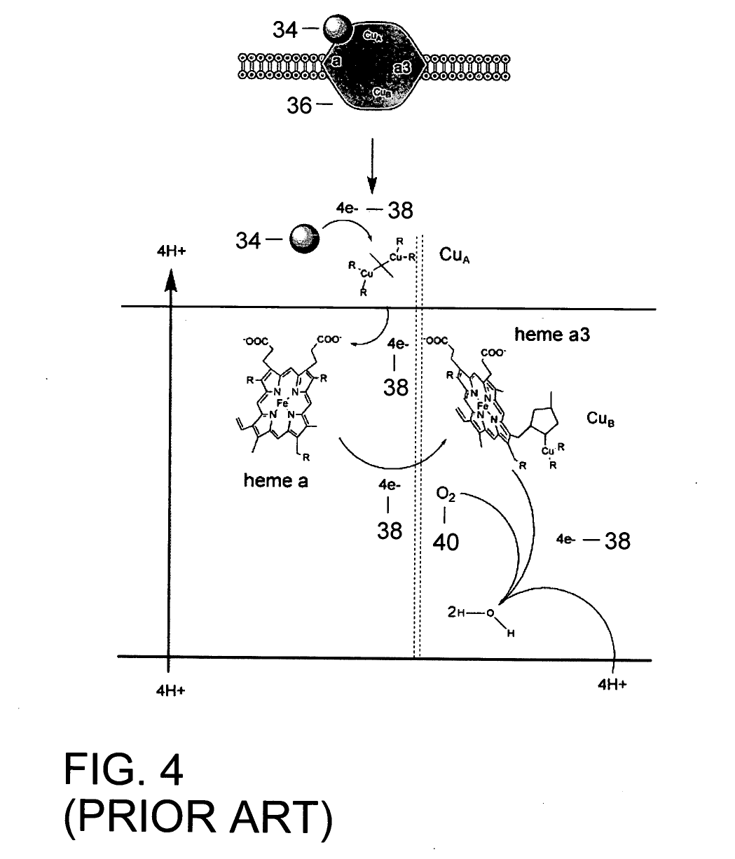

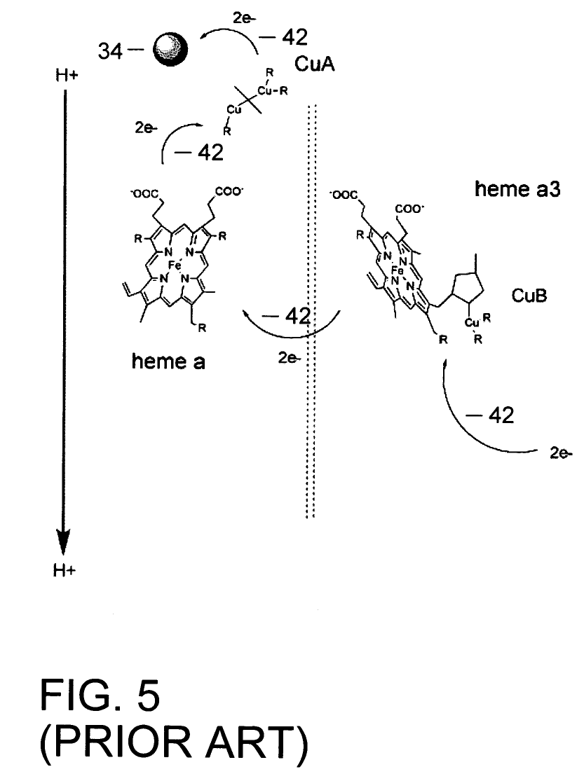

Cytochrome c Oxidase 36 (200 kDa) is a complex metalloprotein that provides a critical function in cellular respiration in both eukaryotes and prokaryotes. The enzyme catalyzes the reduction of oxygen to water as shown in FIG. 4 and the energy released in this reaction is used to form a proton gradient ultimately resulting in the synthesis of ATP (Capaldi, Structure and function of Cytochrome c Oxidase, Annu. Rev. Biochem, 1990, 569-596, vol. 59). While the flow of electrons through Cytochrome c Oxidase normally follows a path 38 from Cytochrome c to Cytochrome c Oxidase to oxygen 40, it is possible to alter the electrochemical environment surrounding the protein so that the reverse reaction shown in FIG. 5 occurs. This results in an electron transfer cascade 42 from Cytochrome c Oxidase to Cytochrome c (Wikstrom et al., Energy dependent reversal of the Cytochrome Oxidase reaction, Biochemistry, 1981, 4051-4054, vol. 78, no. 7).

The invention claimed in this patent draws together the functions of the three aforementioned proteins (Bacteriorhodopsin, Cytochrome c and Cytochrome c Oxidase), isolating and tailoring their reactions to convert solar energy into electron flow.

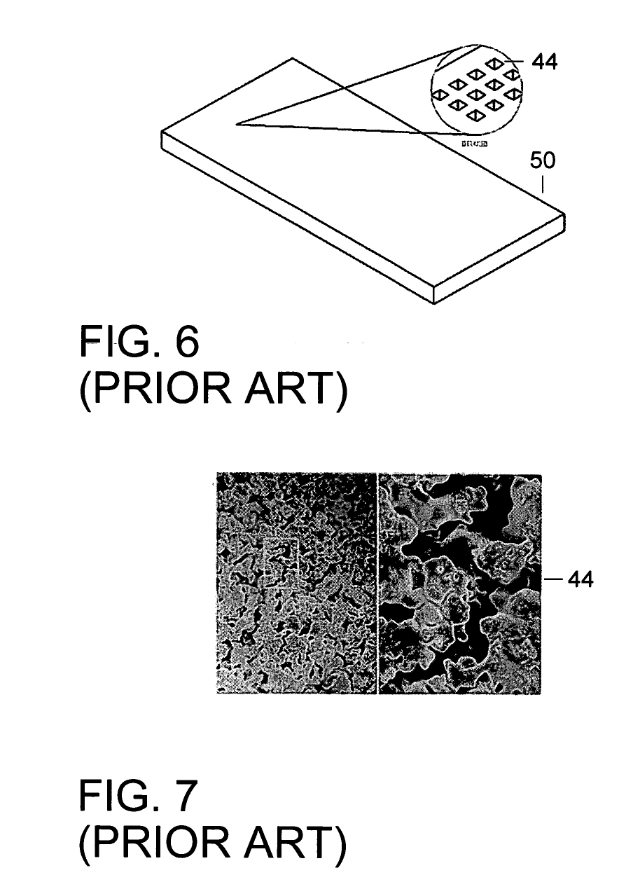

### Detailed Description—FIGS. 6 to 20—Preferred Embodiment

In one component of the system, the protein Cytochrome c is tethered and immobilized to a planar microporous gold electrode shown in FIG. 6 through chemical modification. The microporous gold electrode is fabricated by coating one surface of a nylon membrane with gold using plasma sputtering under the following conditions: time 500 s, pressure 75 mTorr, plasma current 25-30 mA, potential 350-500V. Deposition of gold on one side of the nylon membrane under the given conditions does not result in electrical shunt and preserves the microporosity of the electrode as shown in FIG. 7 (Zhang et al., Gold Nanoparticle-Based Mediatorless Biosensor Prepared on Microporous Gold Electrode, Electroanalysis, 2005, 217-222, vol. 17, No. 8). The nylon material can be a compatible Nylon 6-6 composite.

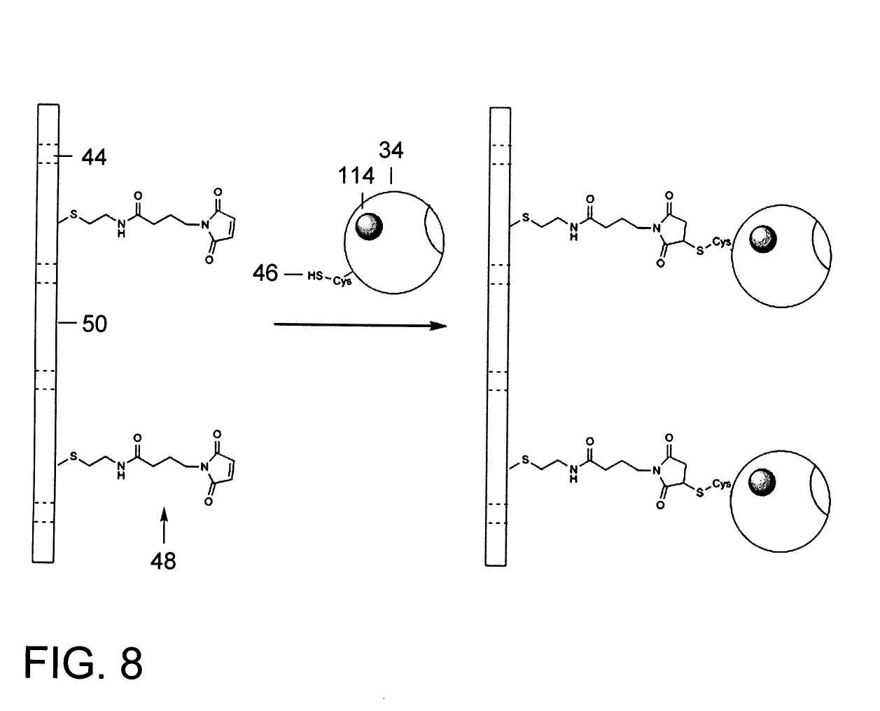

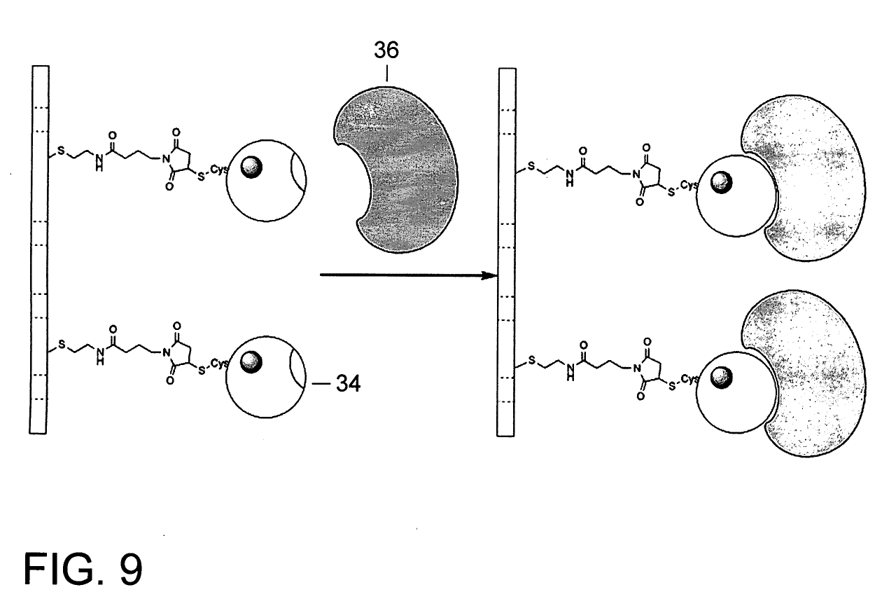

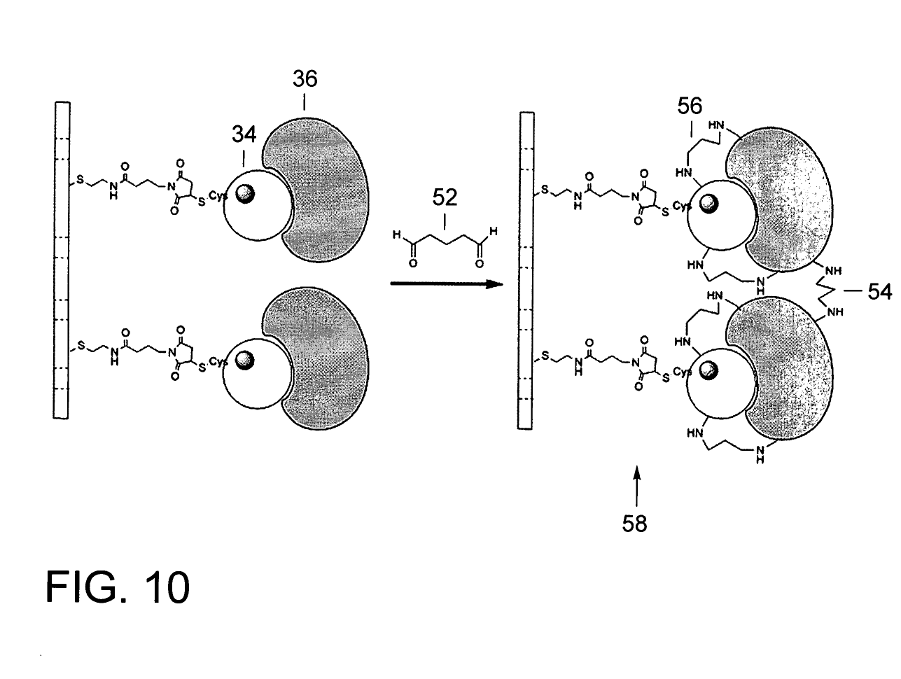

The porous gold electrode is soaked in 0.2M 2,2′-diaminodiethyldisulfide for 2 hours followed by rinsing and reaction with 0.001M of N′-succinimidyl-3-3-maleimidopropionate in DMSO for 2 hours. This treatment results in an organic tether at locations on the electrode not occupied by a pore 44. The electrodes are rinsed and treated with Cytochrome c solution that has been previously oxidized in a desalting column using 1 mg/mL of ferricyanide. The cysteine-102 residue 46 on the Cytochrome c protein contains the only sulfhydryl group that binds to the maleimide layer 48 on the electrode 50. This process generates a modified gold electrode with Cytochrome c molecules attached by an organic linkage as shown in FIG. 8. This modified electrode is interacted with a 0.5 mM Cytochrome c Oxidase solution for 2 hours where Cytochrome c Oxidase attaches to Cytochrome c by natural biological affinity as shown in FIG. 9. Finally, a 10% solution of glutaric dialdehyde 52 is added for 30 minutes. The addition of this chemical results in the cross-linkage of Cytochrome c Oxidase 54 molecules to each other as well as the linking 56 of Cytochrome c molecules to Cytochrome c Oxidase. This linkage 56 is a highly ordered, assembled and oriented monolayer of Cytochrome c Oxidase in electrical connection with Cytochrome c and the electrode as shown in FIG. 10 (Vered Pardo-Yissar et al., Biomaterial Engineered Electrodes for Bioelectronics, Faraday Discussions, 2000, 119-134, vol. 116). The modified microporous electrode 58 is cleaned and stored carefully in cool conditions (<4° C.) until needed.

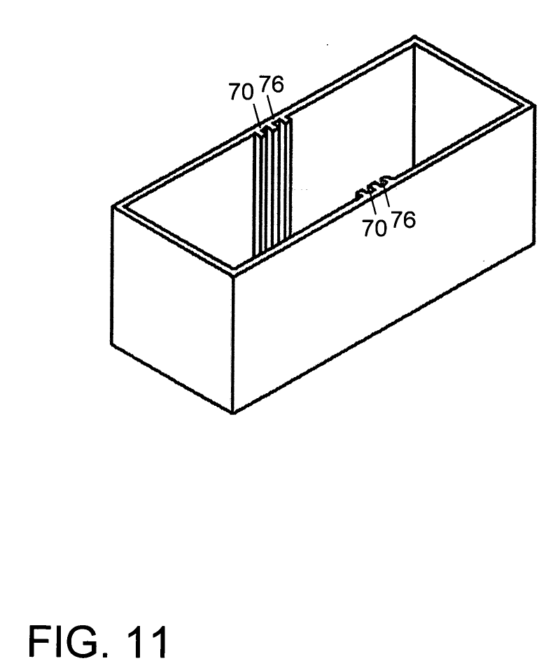

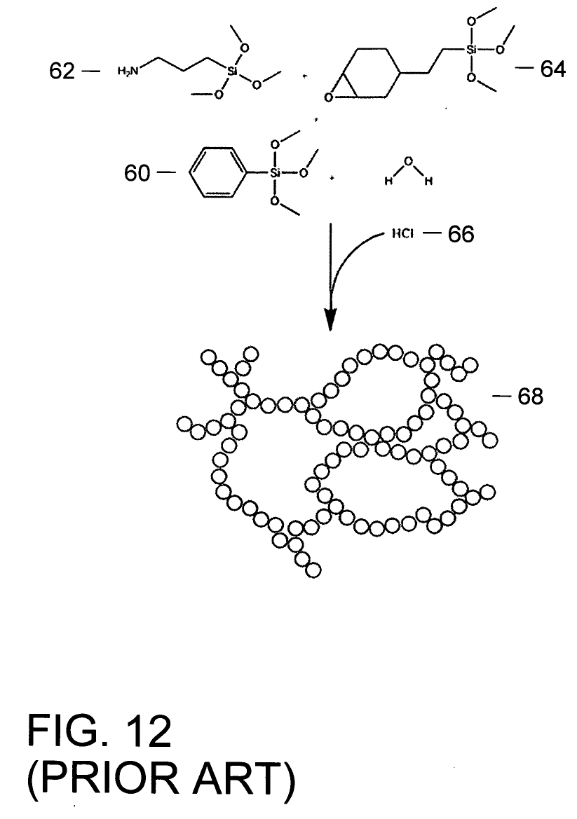

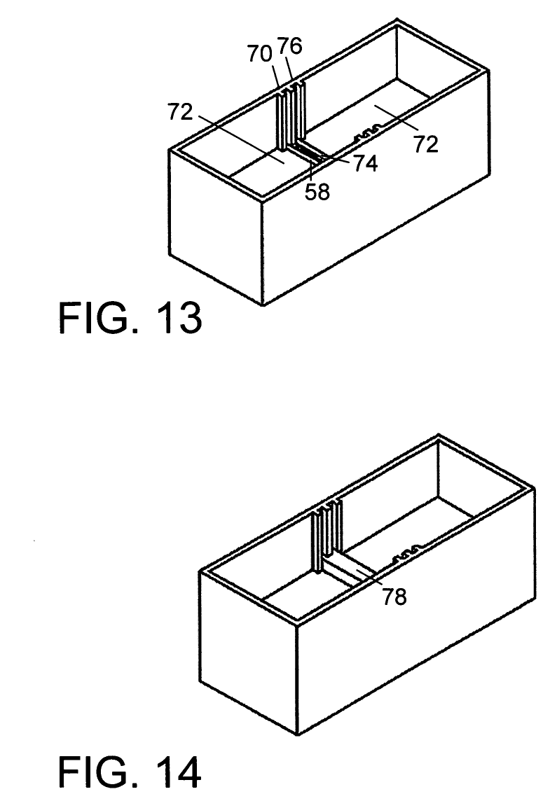

In another component of the system, a biocompatible polymer matrix is formed through formation of a sol-gel material in a rectangular mould of predetermined dimensions shown in FIG. 11. In this embodiment, the biocompatible matrix is an organically modified sol-gel (ORMOSIL) shown in FIG. 12. This ORMOSIL is fabricated through the combination of the organic precursors phenyltrimethoxysilane 60, 3-aminopropyltrimethoxysilane 62, and 2-(3,4-epoxycyclohexyl)ethyltrimethoxysilane 64 in various ratios and volumes (Pandey et al., Photoelectrochemistry of ORMOSIL Sandwiched D96N Bacteriorhodopsin, Journal of Sol-gel Science and Technology, 2005, 51-58, vol. 33). Double distilled water is added as the hydrating medium and hydrochloric acid 66 is added as the catalyst for gelling resulting in a matrix of long chain mixtures of precursor monomers 68. Prior to complete gelation, the modified electrode shown in FIG. 10 is inserted into the first set of grooves 70 in the sides of the mould so that electrode 58 is completely submersed in the bottom ORMOSIL gelling solution 72. Immediately thereafter, a counter electrode 74 is inserted into the second set of grooves 76 in the mould, parallel to the first electrode. Electrode 74 is inserted as close as possible to electrode 58 as shown in FIG. 13.

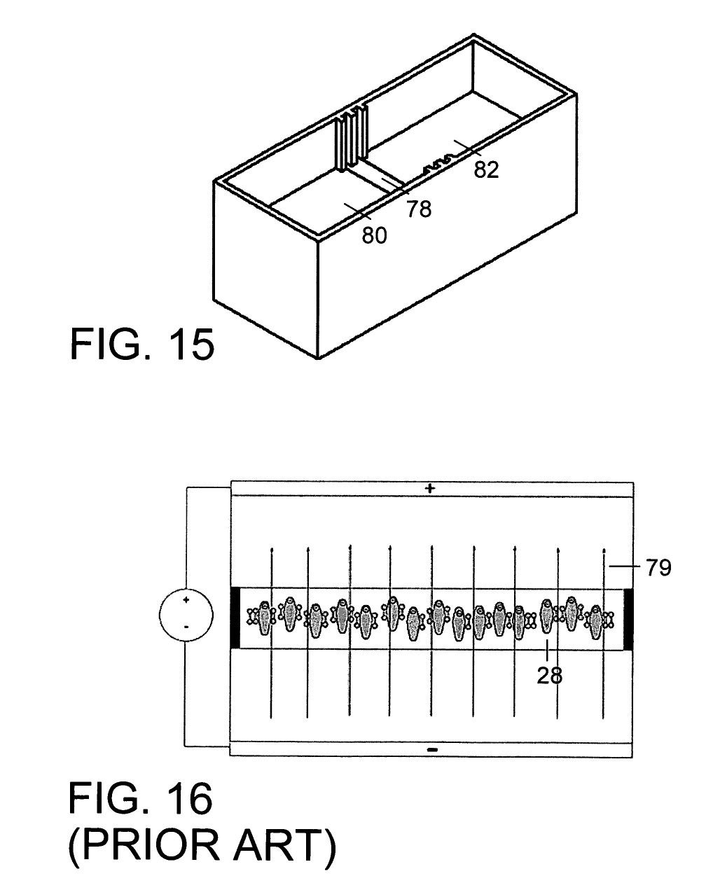

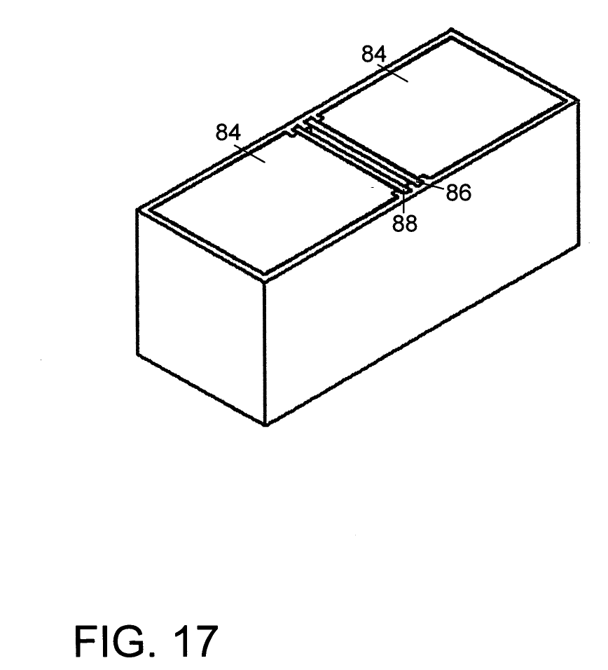

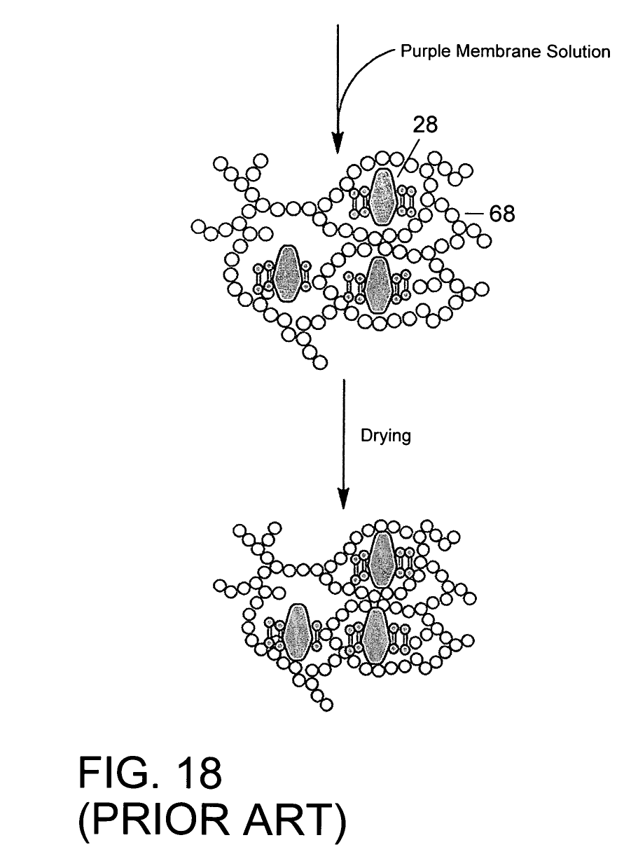

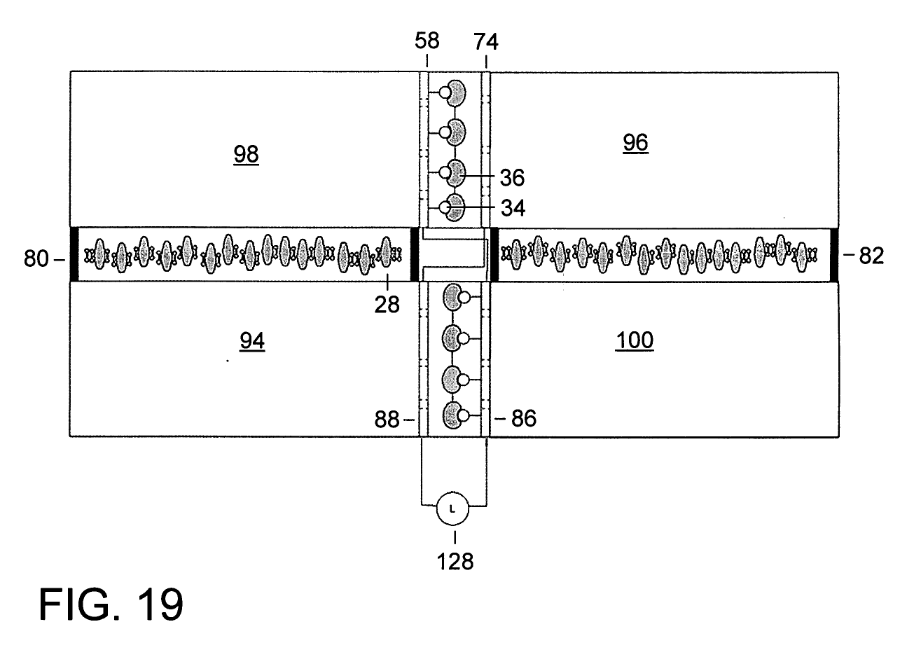

Upon gelation of the bottom layer of ORMOSIL containing 58 and 74, a spacer 78 is inserted into the grooves so that it rests immediately above the first set of electrodes in FIG. 14. Isolated purple membrane solution is deposited onto the ORMOSIL layer on each side of the inserted spacer in FIG. 15. Each layer of purple membrane is oriented through the application of a ˜20V/cm electric field 79 as shown in FIG. 16. Each layer is oriented in a direction opposite to the other. One layer of purple membrane 80 is oriented towards the polymerized sol-gel while the other layer 82 is oriented away. After drying of the purple membrane solution (˜24 hrs), a second and identical layer of ORMOSIL 84 is deposited into the mould in FIG. 17 and on top of the purple membrane layers. This effectively sandwiches the protein and completely immobilizes it in a matrix as shown in FIG. 18 that allows it to function optimally over an extended period of time (greater than 1.5 yrs). In a manner identical to that previously described, another electrode 86 identical to electrode 58 is inserted into the grooves and gelling matrix along with a counter electrode 88 identical to electrode 74. However, the orientation of these two electrodes is alternated so that the protein-modified electrode is located opposite to the modified electrode 58 below it. The entire system is allowed to gel in the mould to form the functional power unit in FIG. 19.

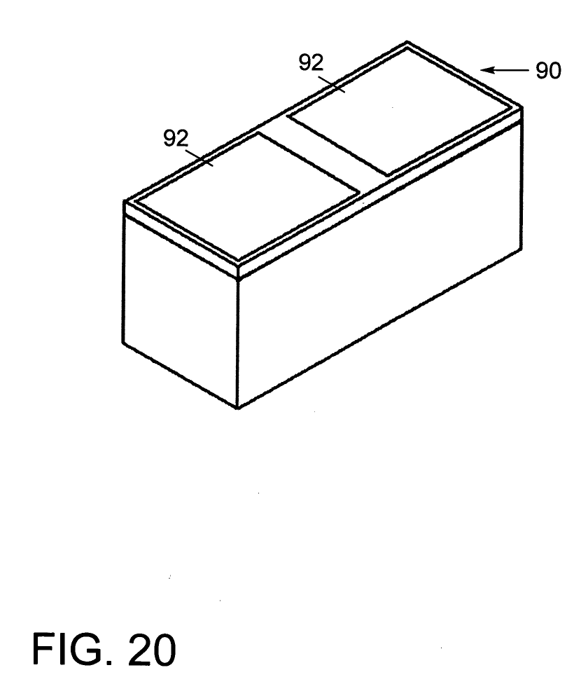

A protective cover unit 90 is placed over the top of the device and attached to the mould as shown in FIG. 20. The cover unit consists of transparent panels 92 over the sol-gel and Bacteriorhodopsin layers within an opaque frame made of an insulating material. The opaque frame extends around the perimeter of the device and over the Cytochrome c/Cytochrome c Oxidase monolayer as well as the electrodes.

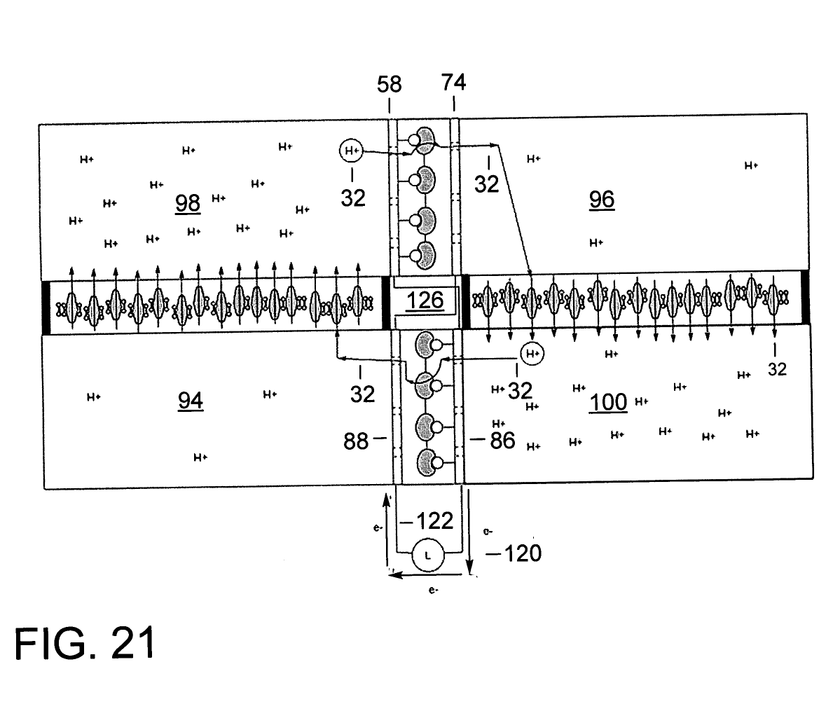

### Operation—FIGS. 21, 20

Upon absorption of photons of incident light in the 500-650 nm wavelength range, Bacteriorhodopsin protein molecules in layers 80 and 82 undergo a conformational change: the all-trans retinal molecule embedded within the Bacteriorhodopsin proton channel is converted into the 13-cis form in a photoisomerization reaction. This physical transformation results in a cascade of reactions in each Bacteriorhodopsin molecule that causes a translocation of one proton per protein from compartments 94 and 96 to compartments 98 and 100 respectively. Collectively, this results in a pH gradient achieved between 94 and 96 and 98 and 100. Functioning optimally, oriented Bacteriorhodopsin can achieve a pH gradient of 4 units across the cell membrane, effectively making the cytosolic side 10 000 times more alkaline than the extracellular side.

The sol-gel layers in the present invention serve a dual intent: they immobilize and stabilize the proteins in their active state and act as a proton-transporting matrix. Sol-gel materials are oxygen-bridged frameworks generated by silicate precursors that form pore networks. These pore networks immobilize the macromolecular protein structures while encouraging the mobility of small species, such as protons. ORMOSIL is an organically modified type of sol-gel that is composed of precursors tailored specifically to bind to protein groups, immobilizing and stabilizing them more effectively. Upon gelation of sol-gel, water molecules are entrapped within the pore structures. This allows for a highly ordered solid solution in which proton conduction is possible. Furthermore, these polymers are stable under a wide range of environmental conditions including temperature and humidity. Finally, the sol-gel material, upon polymerization retains optical clarity and is ideal for applications in which transmission of light is important.

When the Bacteriorhodopsin molecules are oriented and sandwiched between the two ORMOSIL layers 72 and 84 forming protein layers 80 and 82, the Bacteriorhodopsin functions as a proton transporting moiety, moving protons out of one compartment and into the other. As light continues to penetrate the upper sol-gel layer 84 and interact with the Bacteriorhodopsin molecules in layers 80 and 82, the Bacteriorhodopsin causes an accumulation of protons in compartments 98 and 100 and a deficiency in compartments 94 and 96. This charge accumulation and depletion results in a potential energy gradient across the Cytochrome c/Cytochrome c Oxidase monolayer coated electrodes.

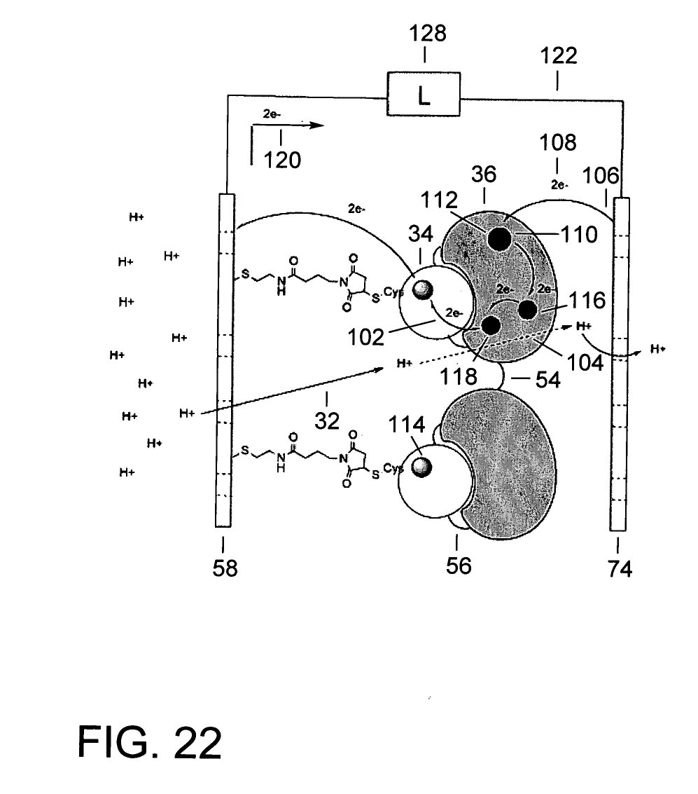

With a high proton concentration to the left of electrode 58 coupled with a proton deficiency to the right of electrode 74, proton flow is encouraged through the permeable electrode 58 as shown in FIG. 22. Due to the porous nature of the electrode, the Cytochrome c layer is prevented from fully coating the electrode surface. However, Cytochrome c Oxidase is significantly larger in diameter than Cytochrome c and upon linking with the smaller, more dispersed Cytochrome c, forms a complete and dense monolayer. The saturated layer of Cytochrome c Oxidase is further linked with glutaric dialdehyde making it such that the path of least resistance for proton flow, after passing through the electrode, is through a Cytochrome c Oxidase proton channel 104. It has been demonstrated that the reversal of the natural proton flow through Cytochrome c Oxidase generates the reverse half-reaction to occur during which water is converted to oxygen, generating electrons:

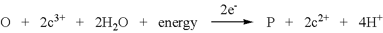

O and P represent the two different states of Cytochrome c Oxidase. c³⁺ and c²⁺ represent the oxidized and reduced forms of Cytochrome c respectively. The energy term represents the electrochemical gradient across Cytochrome c Oxidase generated, in this instance, by the Bacteriorhodopsin layers (Wikstrom et al., Energy dependent reversal of the Cytochrome oxidase reaction, Biochemistry, 1981, 4051-4054, vol. 78, no. 7).

The reverse reaction is facilitated by the potential energy of the proton gradient generated by the Bacteriorhodopsin layers 80 and 82. However, in an environment where free electrons 106 are readily available, the more favourable reverse reaction will be the accepting 108 of these free electrons by Cytochrome c Oxidase heme a3 110 and Cu_{B} 112 groups rather than the more energetically expensive process of removing the electrons from oxygen. The electrons are easily transferred to the heme a group 116 and the Cu_{A} group 118 followed by the energetically favourable transfer 102 to the heme group 114 of Cytochrome C. The organic tether linking Cytochrome c to electrodes 58 and 86 positions the protein in such a way that electron transfer to electrodes 58 and 86 is spatially and kinetically favourable. While this final electron transfer is already favourable, it is further encouraged by the initial oxidation of the Cytochrome c with ferricyanide. This oxidation encourages the protein to act as a proton acceptor rather than donor. The proximity of Cytochrome c to electrode 58 coupled with the electromotive force generated by the Cytochrome c Oxidase, results in electron donation from the Cytochrome c molecule to electrode 58. This transfer coupled with Cytochrome c Oxidase removing electrons from electrode 74 encourages cyclic electron flow 120 through the circuit 122. The mechanism described in this section is mirrored in an identical but oppositely oriented Cytochrome complex 124. Both modified electrodes 58 and 74 are wired together and both counter electrodes 86 and 88 are wired together forming a series connection 126 of both the electrodes.

As protons flow through the Cytochrome c Oxidase molecules from compartments 98 and 100 to 96 and 94 respectively, the pH gradient is maintained and the oppositely oriented Bacteriorhodopsin layers 80 and 82 are allowed to continue pumping protons in a cyclic fashion through the device. Consequently, the protons are continually cycled through all four compartments causing electrons to be cycled through the external load 128.

The protective cover unit 90 protects the internal components of the device from excessive heat as well as from other environmental conditions while allowing the transmission of all incident light. The frame allows light to make contact only with the more thermally and optically stable Bacteriorhodopsin and prevents light from interacting with the more sensitive and less stable Cytochrome c/Cytochrome c Oxidase complexes. The design ensures that light only interacts with components of the device suited to sun exposure.

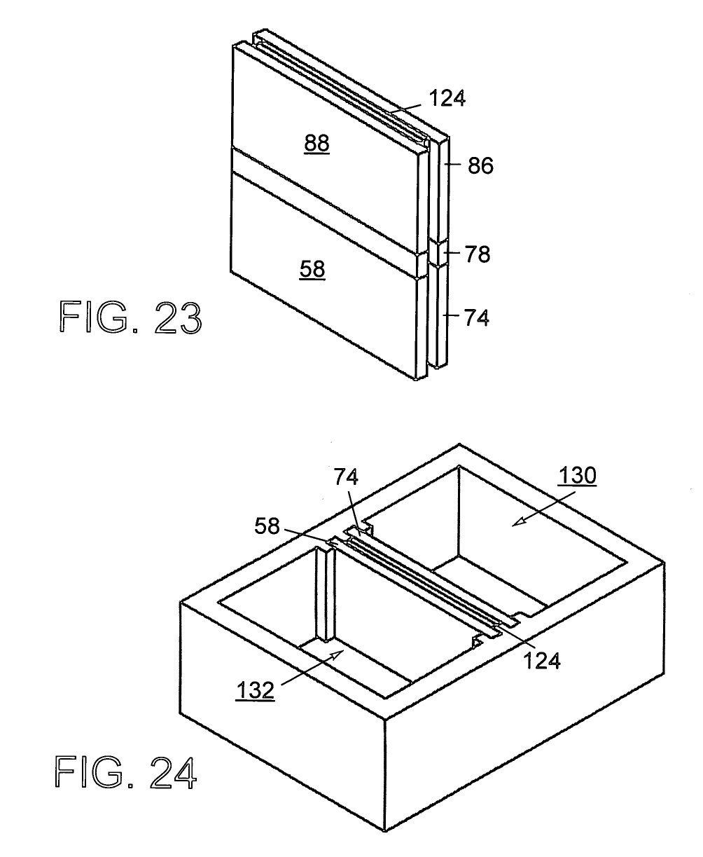

### FIGS. 23-27—Alternate Embodiments

Alternate embodiments of the present invention are possible. Substituting individual components of the system for specific applications is simple. For example, in an additional embodiment of the present invention the microporous gold electrodes are prepared by sputter deposition of approximately 60 nm of gold onto both sides of a stainless steel frit using an LCV-100 cold sputter-etch unit (Plasma Sciences, Lorton, Va.). The frit maintains its microporous structure following gold deposition as shown by scanning electron microscopy shown in FIG. 7. However, the pore sizes may be less uniform than those created using a standardized nylon material (Ducey Jr. et al., Electroanalysis, Microporous Gold Electrodes as Combined Biosensor/Electrochemical Detectors in Flowing Streams, 1998, vol. 10, No. 3).

In another embodiment of the invention, the sol-gel (ORMOSIL) material is replaced with an aqueous electrolyte solution. A thermally stable electrolyte can aid in both proton conduction and protein protection. A nylon microporous membrane like the one used for the electrodes in FIG. 6 can be impregnated with a polymer/Bacteriorhodopsin solution that is oriented and dried. This nylon membrane can then be used to separate the aqueous compartments. Furthermore, the portion of the sol-gel surrounding the Cytochrome molecules (between the modified and counter electrodes) can be replaced with an aqueous phase electrolyte conditioned to protect the Cytochrome molecules. Since the Cytochrome molecules are fully protected from incident light by the spacer and protective cover, the possibility that the aqueous solution may degrade or evaporate through exposure to the sun is reduced or eliminated.

It is also possible to implement a modular design in which certain components of the system can be removed. For example, a unit consisting of the modified electrodes 58 and 86 and counter electrodes 74 and 88 along with the Cytochrome c/Cytochrome c Oxidase monolayer and spacer 78 can be fabricated as one, removable unit as shown in FIG. 23. If the Cytochrome c or Cytochrome c Oxidase or electrodes degrade over time, only that specific component of the device can be removed and replaced. This is a further advantage of having separate compartments and layers for each protein.

The unit in FIG. 23 can act as a device in itself. Acting as the barrier between two isolated compartments each with a differing acidity (pH), this unit (or just the half above or below the spacer) can effectively convert pH gradients (differences in acidity) into useable electricity. For example, the device can be used in an acid-based fuel cell where the fuel is injected into one compartment 130 on one side of the two-celled device as shown in FIG. 24. If the compartment 132 on the other side of the device is less acidic, neutral or basic in character, the protons will flow down their concentration gradient and into the second compartment 132 generating electricity through the circuit. By flowing from the first compartment to the second, the protons will be forced through the Cytochrome c Oxidase molecules in the monolayer between the electrodes driving the reverse half-reaction as shown in FIG. 5. It is this half-reaction that will drive electrons through a circuit. Eventually both compartments of such a device will attain a pH (acidity) balance and the cell must be refuelled.

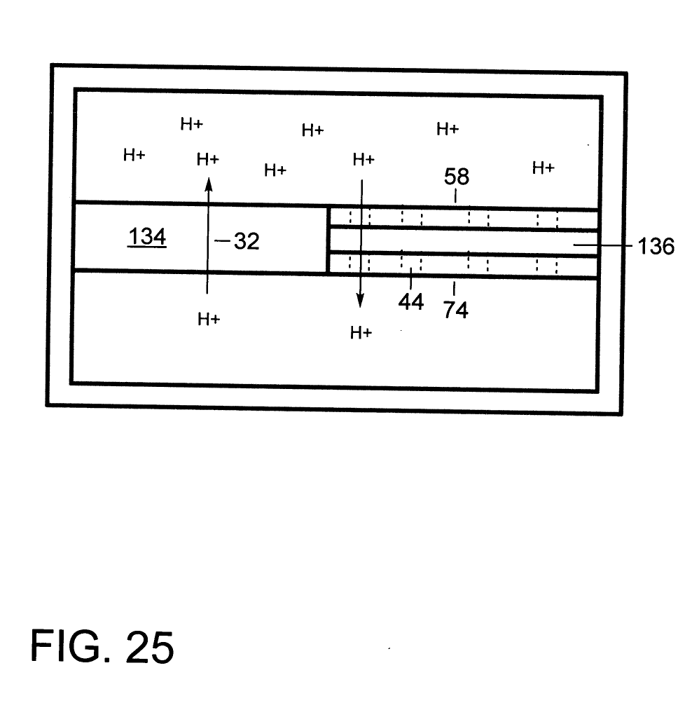

In another embodiment of the invention, the electrodes and the purple membrane layers may be positioned in various orientations. Rather than placing the electrodes perpendicular to the Bacteriorhodopsin layers, they may be placed in a parallel configuration as shown in FIG. 25. Separate layers of Bacteriorhodopsin 134 and electrode-sandwiched Cytochrome proteins 136 can be manufactured independently and subsequently integrated into a parallel sheet. In this way, each protein may be independently oriented and conditioned. In such a device, the Bacteriorhodopsin molecules pump protons above the Cytochrome and electrode layer 136 and the protons then filter back through the device only to be pumped back up again by the Bacteriorhodopsin layer.

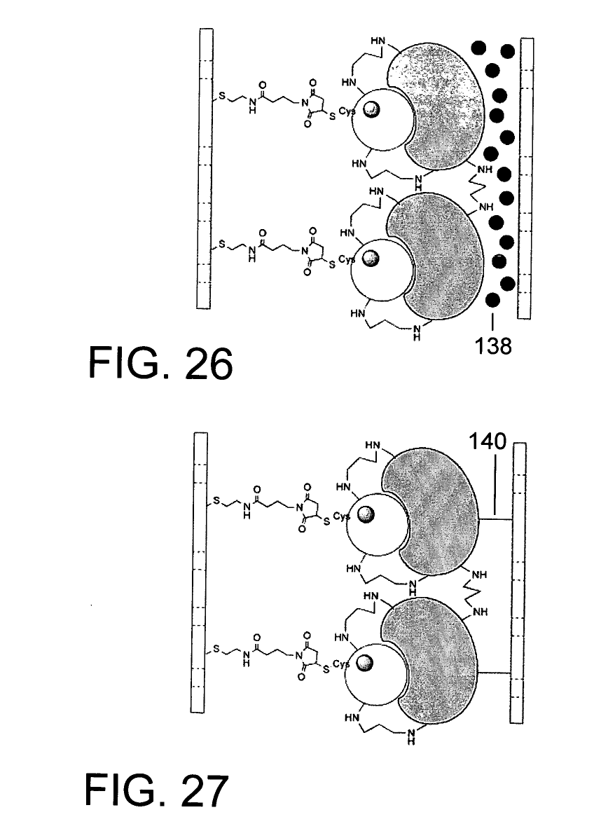

In another embodiment of the invention, the efficiency of the reverse half-reaction may be improved through the doping of the sol-gel with a conducting material 138 such as gold, palladium or graphite particles as shown in FIG. 26 (Gill et al., Bioencapsulation within synthetic polymers (Part 1):sol-gel encapsulated biologicals, 2000, 282-296, vol. 18). This doping encourages electron transfer directly from the counter electrodes to the Cytochrome c Oxidase electron accepting groups (Cu_{B} 112 and Heme a3 110). An additional embodiment consists of tethering 140 the electron-accepting end of Cytochrome c Oxidase (Cu_{B} 112 and heme a3 110 groups) to the counter electrode as shown in FIG. 27. This ensures that electron transfer and electrode spacing is optimal. The tether 140 can consist of any organic or synthetic linkage that efficiently connects the molecule to the electrode without impeding its function or electron transfer characteristics.

Another embodiment of the present invention uses genetic variants of the proteins Bacteriorhodopsin, Cytochrome c and/or Cytochrome c Oxidase in order to improve the efficiency of the cell. In one embodiment, a number of Bacteriorhodopsin mutants are used to absorb wavelengths of light over a wider range. Such mutants are derived through the substitution of amino acids in the wild-type protein (Tittor et al., Inversion of Proton Translocation in Bacteriorhodopsin Mutants D85N, D85T, and D85,96N, 1994, 1682-1690, vol. 67).

Depending on application-specific energy needs, the dimensions of the cell can be either reduced or increased. Thin solar cells are constructed by decreasing the height of the electrodes. Thin cells with thin electrodes can be connected in series and parallel configurations to increase both current and voltage output. If weight and size are not an important consideration, the cell can be made deeper, longer and wider in order to increase the surface area of the electrodes, thus increasing power output.

The device as described in this patent or with slight modifications can be made to suit numerous applications. Constructed on a small scale, the device is a highly efficient optoelectronic switching device. The switching time of the Bacteriorhodopsin is extremely fast and ideally suited to electronics. Furthermore, the device can be used as a light measuring instrument or light sensor in its current embodiment. Additionally, the mould surrounding the internal components can be made transparent and the concentration of purple membrane can be varied so that the majority of the cell is completely transparent. If such a transparent cell were to be encased in glass, it would serve as an efficient energy-converting window. Such a window could be used to power homes and buildings simply by replacing or modifying standard windows.

Another method of manufacturing the components of the Protein-Coupled Bioelectric Solar Cell of the present invention is through the use of inkjet printing technology. Using a modified standard inkjet printer, the protein and sol-gel materials can be accurately and efficiently deposited in carefully constructed layers. This technique allows construction of the cell with minimal loss of material (Boland et al., Cell and organ printing: 1: Protein and cell printers, The Anatomical Record A, 2003, 491-496, vol. 272A).

### CONCLUSION, RAMIFICATIONS, SCOPE

Accordingly, the reader will see that the Protein-Coupled Bioelectric Solar Cell of the present invention can be used to generate useable electricity from solar energy. Through compartmentalization of the proteins Bacteriorhodopsin, Cytochrome c and Cytochrome c Oxidase along with their discrete biochemical reactions, a highly controlled and efficient conversion of solar energy is achieved. Further control is obtained through the use of organically modified sol-gel (ORMOSIL) polymers that effectively immobilize proteins while maintaining the functional efficiency observed in their natural environment. Furthermore, the use of such polymer gels allows the cell to be constructed absent of aqueous materials, but still retaining proton conductivity—a very attractive commercial benefit previously unexploited in biologically based devices of this nature.

Entrapped within these gels, layers of Bacteriorhodopsin are able to establish the cyclical flow of protons, unique to the compartmentalized design of the present invention. Also in combination with the polymer gel, the Cytochrome c/Cytochrome c Oxidase compartment achieves a high degree of regulation using organic tethers to efficiently orient and link the proteins to the electrode. This linkage optimizes the conversion of the proton flow into an electron flow. The use of microporous electrodes allows the tethering of the Cytochrome c molecules, yet ensures that the tethers are moderately dispersed to prevent inter-linking of the smaller Cytochrome c proteins. In addition, the microporosity of the electrodes allows the protons to move through the electrodes so that they may interact with the proteins. Furthermore, the Protein-Coupled Bioelectric Solar Cell has additional advantages in that
it is inexpensive to manufacture
the active biological material is composed of proteins that are immobilized and highly stabilized
it is a compartmentalized design that couples Bacteriorhodopsin and the Cytochrome protein reactions effectively and efficiently
it allows the Bacteriorhodopsin and the Cytochrome proteins to be oriented separately and therefore, more efficiently
it allows the proteins to exist in separate layers so as to increase the amount of photoactive material exposed to sunlight thereby increasing efficiency
it allows the cell to be constructed in the solid state, absent of aqueous media
it allows the protection of biological materials not suited to sun exposure from all incoming light
it allows for optimal electron transfer to the modified electrode through the use of the Cytochrome c protein to complete an electron pathway from Cytochrome c Oxidase to an electrode
it may be partially transparent and aesthetically superior to conventional solar technologies

For the sake of simplicity, the present invention shall be referred to as ‘cell’ for the purposes of this paragraph. Although the description above contains many specificities, these should not be construed as limiting the scope of the invention but as merely providing illustrations of some of the presently preferred embodiments of this invention. For example, the cell is not limited by the number of compartments (i.e. four); the cell is not limited to perpendicular orientation of adjacent protein layers; the cell is not limited in length, width or height, or colour; the cell is not limited to power production; the proteins in the cell are not limited to one configuration and may be oriented and immobilized by various methods; the cell is not limited to the wild-type variants of the proteins; the cell is not limited to the use of ORMOSIL or sol-gel materials or any specific sol-gel precursors; the electrodes in the cell are not limited to any specific material, such as gold or any parameter such as pore size; the cell is not limited to solid state materials and may be constructed using aqueous electrolytes.

Thus the scope of the invention should be determined by the appended claims and their legal equivalents, rather than by the examples given.

1. A compartmentalized solar energy converting cell comprising
a. proton-pumping photoactive biological layers sandwiched between a proton conducting material
b. microporous active and counter conductive electrodes
c. a biological complex that converts a proton gradient into electromotive force
d. a means for coupling said photoactive layers and said biological complex
whereby the compartmentalization of said solar energy converting cell and the coupling of said photoactive layers and said biological complex result in the conversion of solar energy into a cyclical proton flow and subsequent electron flow.

2. The compartmentalized cell of claim 1 wherein said proton-pumping photoactive biological layers comprise oriented purple membrane, Bacteriorhodopsin or any of its genetic variants.

3. The compartmentalized cell of claim 1 wherein said proton conducting material is a polymer sol-gel.

4. The compartmentalized cell of claim 3 wherein said polymer sol-gel is an organically modified sol-gel material (ORMOSIL).

5. The compartmentalized cell of claim 1 wherein said biological complex for converting said proton gradient is a monolayer of Cytochrome c and Cytochrome c Oxidase or any of their genetic variants.

6. The compartmentalized cell of claim 5 wherein said Cytochrome c is oriented and organically linked to said microporous active electrodes.

7. The compartmentalized cell of claim 5 wherein said Cytochrome c Oxidase proteins are organically linked to each other forming an impermeable layer around said Cytochrome c Oxidase.

8. The compartmentalized cell of claim 1 wherein said microporous electrodes have a pore size smaller than the diameter of said Cytochrome c Oxidase.

9. The compartmentalized cell of claim 1 wherein said microporous active and counter electrodes sandwich said biological complex.

10. The compartmentalized cell of claim 9 wherein said microporous active and counter electrodes and said biological complex are encapsulated in said proton-conducting material.

11. The compartmentalized cell of claim 10 wherein said proton-conducting material is a doped sol-gel further enabling electron conductivity from said counter electrode to said biological complex.

12. The compartmentalized cell of claim 1 wherein said proton-pumping photoactive biological layers are positioned to establish a proton gradient across said biological complexes.

13. A method of generating electricity from solar energy comprising
a. multiple photoactive layers between isolated compartments that generate proton gradients across said compartments
b. multiple layers consisting of the protein Cytochrome c Oxidase linked to the protein Cytochrome c that is linked to a microporous electrode
c. said proton gradient forcing flow of protons through said Cytochrome c Oxidase layer
d. the reverse half-reaction of Cytochrome c Oxidase transforming the potential energy of said proton gradient into electromotive force

14. The method of claim 13 wherein said photoactive layers comprise oriented Bacteriorhodopsin, purple membrane or any of its genetic variants.

15. The method of claim 13 wherein said photoactive layers are oriented oppositely on either side of oppositely oriented Cytochrome c Oxidase layers deriving cyclic proton and electron flow.

16. A device for transforming potential energy into electron flow comprising
a. a layer consisting of Cytochrome proteins
b. active and counter microporous electrodes
c. a conducting matrix
whereby said device is placed in a potential energy gradient to convert said gradient into electricity

17. The device of claim 16 wherein said layer consisting of Cytochrome proteins is oriented and linked to said active microporous electrode.

18. The device of claim 17 wherein said microporous counterelectrode is placed as close as possible to said active electrode.

19. The device of claim 17 wherein said Cytochrome proteins and said microporous electrodes are embedded in a proton conducting matrix.

20. The device of claim 18 wherein the device separates two compartments of a fuel cell wherein the fuel powering said fuel cell is an acid.
